(19) United States
(12) Patent Application Publication
(10) Pub. No.: US 2026/0343761 A1
(43) Pub. Date: Oct. 29, 2026

(54) MODULAR CASING WITH HANDLE

(71) Applicant: ACCTON TECHNOLOGY CORPORATION, Hsinchu City (TW)

(72) Inventor: HUNG-YANG WEN, Hsinchu City (TW)

(73) Assignee: ACCTON TECHNOLOGY CORPORATION, Hsinchu City (TW)

(21) Appl. No.: 19/291,640

(22) Filed: Aug. 6, 2025

(30) Foreign Application Priority Data
Apr. 29, 2025 (CN) 202520837063.6

(51) Int. Cl. H05K 5/02

(52) U.S. Cl. CPC H05K 5/023

(57) ABSTRACT

A modular casing with a handle has a casing body including a rear plate. A mounting space is formed inside the casing body. A rear opening is formed on a top portion of the rear plate. The rear opening is engaged with a connecting head of a handle body. A protrusion is formed on the connecting head and extends into the rear opening. A through hole penetrates through the protrusion and the connecting head. A linkage switch is mounted in the through hole. Two ends of the linkage switch respectively form a hook portion and a trigger portion. The hook portion passes from a top surface of the casing body. The trigger portion could be pressed to drive the hook portion to change from extending to retracting.

### BACKGROUND OF THE INVENTION

### Technical Field

The present disclosure relates generally to a device with a handle, and more particularly to a modular casing with a handle.

### Description of Related Art

Devices disposed in a cabinet such as fans are individually fixed within the cabinet. Network communication equipment or computer hosts disposed in the cabinet could be cooled by airflows provided by the fans, thereby preventing malfunctions caused by overheating of the network communication equipment or the computer hosts.

The fans disposed in the cabinet could provide a heat dissipation function. However, as the fans are individually fixed within the cabinet, it is required to mount the fans in the cabinet or remove the fans from the cabinet upon installing, repairing or replacing the fans located within the cabinet, which is time-consuming and inconvenient.

### BRIEF SUMMARY OF THE INVENTION

In view of the above, the primary objective of the present disclosure is to provide a casing, wherein the casing is provided with a handle assembly, and a space for fixing a device to be modularized is formed inside the casing. The casing and the device inside the casing are together mounted in the cabinet, so that the device is modularized and the modularized device could be rapidly mounted in a cabinet or be rapidly removed from the cabinet for maintenance and replacement, thereby facilitating the use of the user.

The present disclosure provides a modular casing with a handle, including a casing body, a handle assembly, and a linkage switch. The casing body has a top plate and a rear plate that are connected to each other. A mounting space is formed inside the casing body. A rear opening is formed on a portion of the rear plate adjacently connected to the top plate. The handle assembly includes a handle body. An end of the handle body is connected to a connecting head. A connecting surface is formed on a side of the connecting head facing the rear plate. A protrusion is formed on a middle of the connecting surface. The connecting surface is engaged with a peripheral edge of the rear opening. The protrusion extends into the rear opening. A through hole is formed inside the protrusion and the connecting head. A hook opening is formed on an end of the through hole facing the casing body. A trigger opening is formed on another end of the through hole facing away from the casing body. The linkage switch is mounted in the through hole. A hook portion is formed on an end of the linkage switch facing the casing body. A trigger portion is formed on another end of the linkage switch facing away from the casing body. The hook portion passes through the top plate of the casing body via the hook opening. The trigger portion is exposed from the trigger opening. The trigger portion is movable between a first position and a second position. When the trigger portion moves from the first position to the second position, the hook portion is driven to change from a state of extending out the top plate to retracting into the hook opening.

When the present disclosure is used, a device to be modularized is fixed in the mounting space of the casing body. With the aforementioned design, the user could hold the handle body and push the casing body and the devices disposed inside the casing body, such as fans, into a cabinet for mounting, so that mounting the fans in the cabinet or removing the fans from the cabinet for repairing and replacing could be time-saving and convenient. In this way, the user could modularize the devices that are required to be disposed in the cabinet such as fans.

Moreover, when the modular casing with the handle is mounted in the cabinet, the hook portion of the linkage switch could be engaged with the locking hole of the cabinet, so that the modular casing with the handle and the fans inside the modular casing with the handle could be fixed in the cabinet. When the fans are required to be removed, the user only needs to press the trigger portion of the linkage switch, so that the hook portion retracts and the modular casing with the handle is released. At that time, the user could pull out the casing body and the fans disposed inside the casing body from the cabinet through the handle body. The operation process is convenient, rapid, and easy.

### BRIEF DESCRIPTION OF THE SEVERAL VIEWS OF THE DRAWINGS

The present disclosure would be best understood by referring to the following detailed description of some illustrative embodiments in conjunction with the accompanying drawings, in which

FIG. 1 is a perspective view of the modular casing with the handle according to an embodiment of the present disclosure;

FIG. 2A is a perspective view of the modular casing with the handle according to the embodiment of the present disclosure seen from another perspective;

FIG. 2B is an enlarged view of the marked region 2B in FIG. 2A;

FIG. 3A is an exploded view of the modular casing with the handle according to the embodiment of the present disclosure;

FIG. 3B is an enlarged view of the marked region 3B in FIG. 3A;

FIG. 4 is a top view of the modular casing with the handle according to the embodiment of the present disclosure;

FIG. 5A is a sectional view along the 5-5 line in FIG. 4;

FIG. 5B is an enlarged view of the marked region 5B in FIG. 5A;

FIG. 6 is a schematic perspective view, showing that the modular casing with the handle according to the embodiment of the present disclosure is mounted into the cabinet;

FIG. 7 is a schematic sectional view, showing that the modular casing with the handle according to the embodiment of the present disclosure is mounted into the cabinet and the trigger portion is located at the second position; and

FIG. 8 is a schematic section view, showing that the modular casing with the handle according to the embodiment of the present disclosure is mounted into the cabinet and the trigger portion is located at the first position.

### DETAILED DESCRIPTION OF THE INVENTION

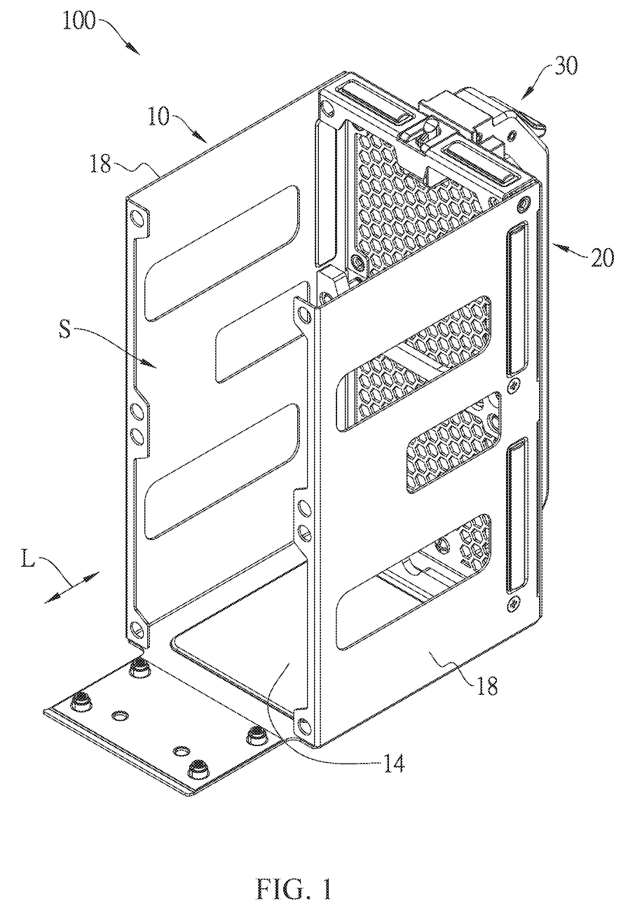

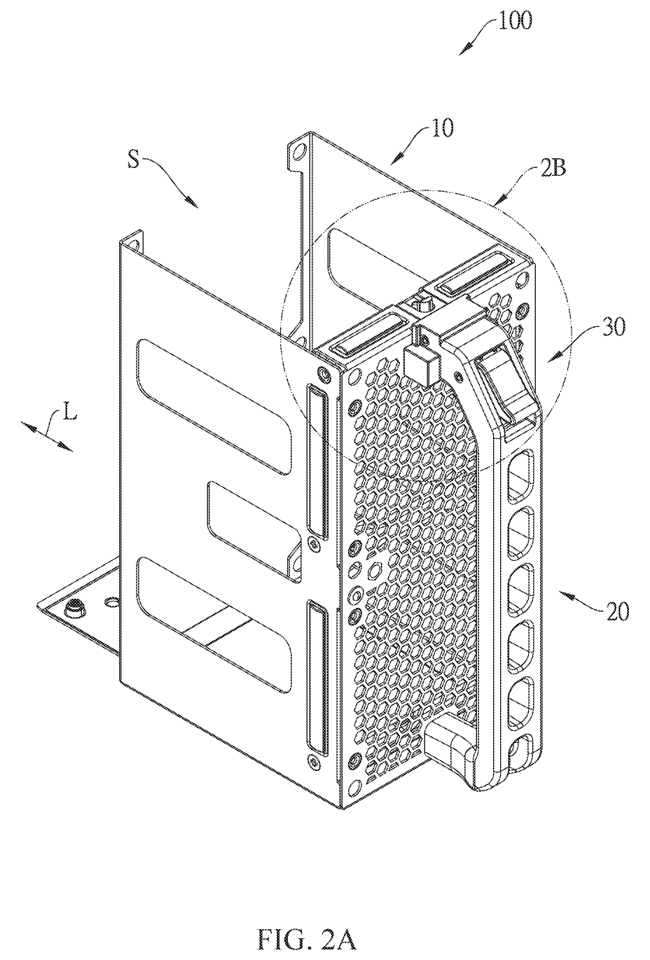

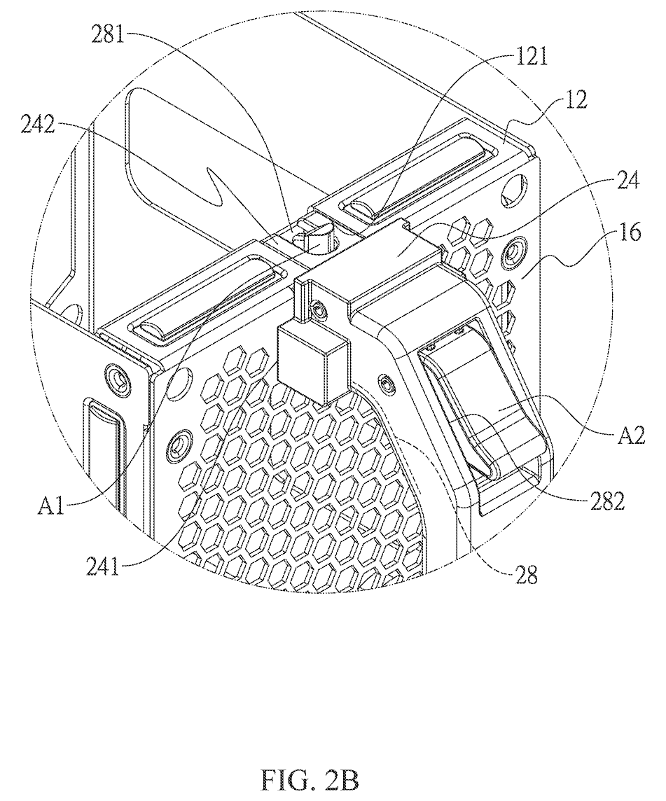

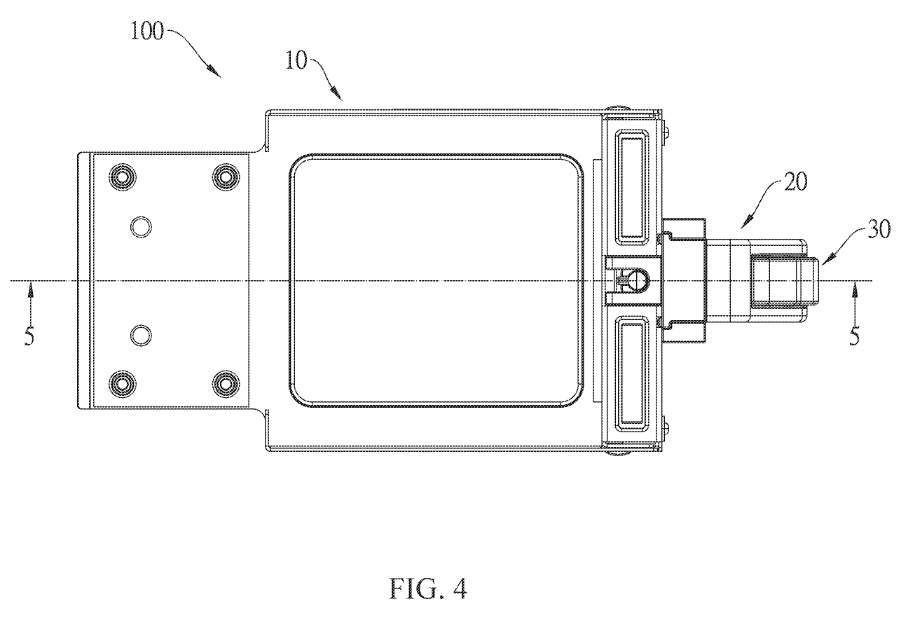

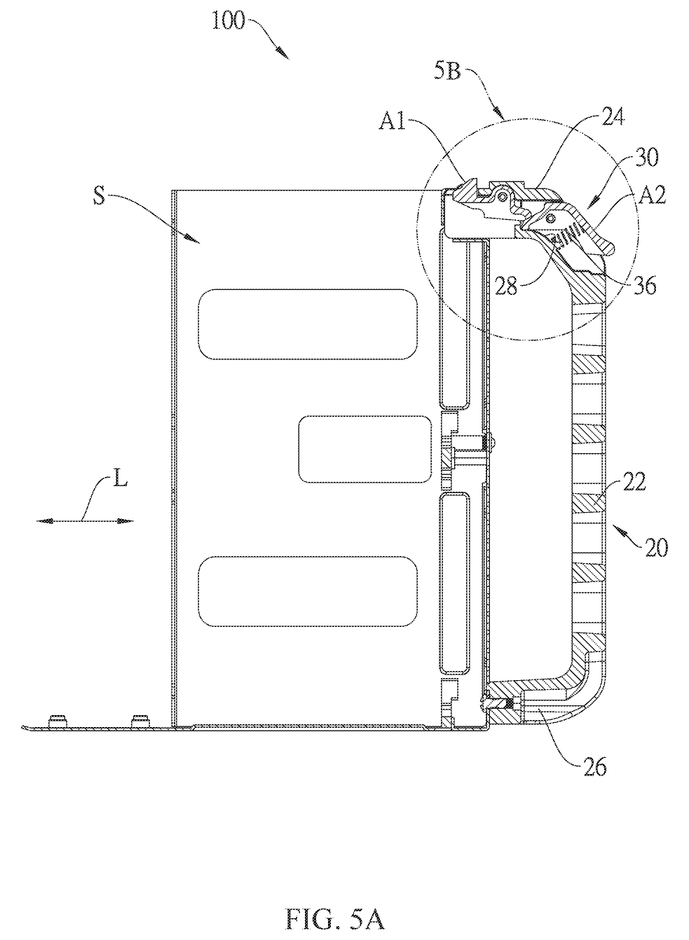

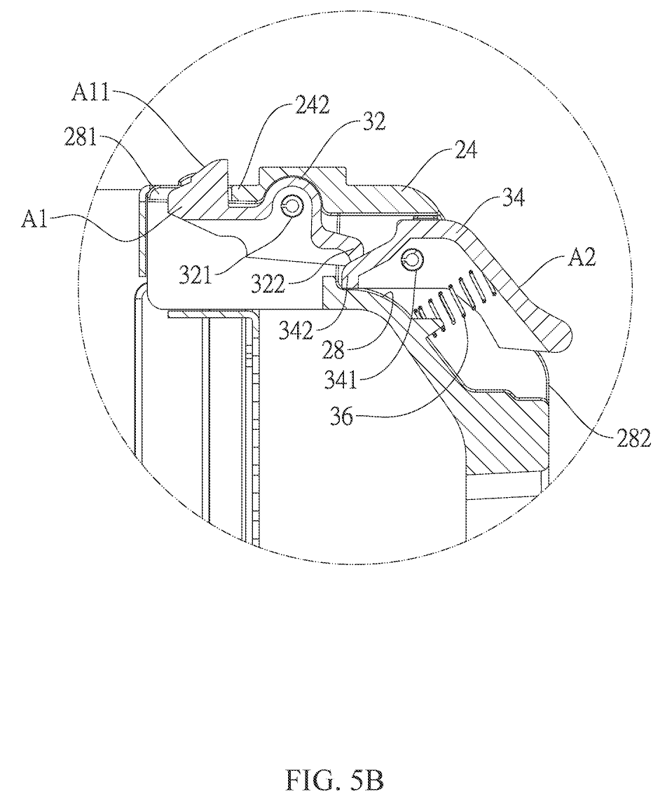

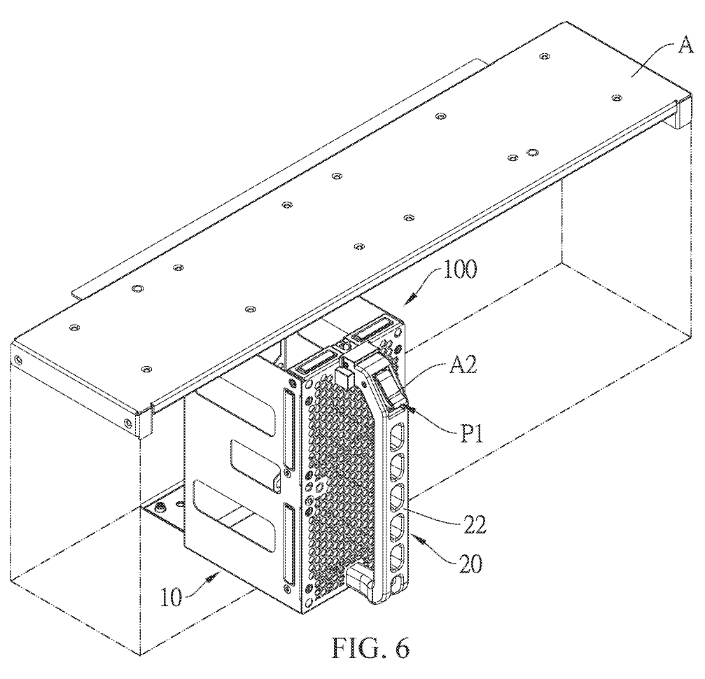

A modular casing 100 with a handle according to a preferred embodiment of the present disclosure is illustrated in FIGS. 1-5B and is configured to fix a device to be modularized within the modular casing 100. In the current embodiment, the device to be modularized is two fans (not shown). Afterwards, the modular casing 100 with the handle and the fans installed within the modular casing 100 are together mounted into a cabinet A along a front-rear direction L as shown in FIG. 6. In the below description regarding the modular casing 100 with the handle, the terms “front”, “rear”, “left”, “right”, “top”, “bottom”, and their derivatives should be interpreted based on the front-rear direction L. It is also understood that the terminology used herein is for the purpose of describing particular embodiments only, and is not intended to limit the scope of the present disclosure. The modular casing 100 with the handle includes a casing body 10, a handle assembly 20, and a linkage switch 30.

The casing body 10 is a housing made of metallic plates. The casing body 10 includes a top plate 12, a bottom plate 14, a rear plate 16, and two lateral plates 18. The top plate 12 and the bottom plate 14 are two plates facing each other along a top-bottom direction. The rear plate 16 is a rectangular plate, wherein a top edge and a bottom edge of the rear plate 16 are short sides. A rear edge of the top plate 12 is connected to the top edge of the rear plate 16. A rear edge of the bottom plate 14 is connected to the bottom edge of the rear plate 16. The two lateral plates 18 are two plates facing each other along a left-right direction. Two bottom edges of the two lateral plates 18 are respectively connected to a left edge and a right edge of the bottom plate 14. A mounting space S is formed inside the casing body 10. The mounting space S is formed between the bottom plate 14, the rear plate 16, and the two lateral plates 18.

A rear opening 161 is formed on a portion of the rear plate 16 adjacently connected to the top plate 12. The rear opening 161 is a rectangular opening. At least one fixing through hole 162 is formed on a peripheral edge of the rear opening 161. In the current embodiment, two fixing through holes 162 are respectively formed on a left side and a right side of the peripheral edge of the rear opening 161. A top opening 121 is formed on a portion of the top plate 12 adjacently connected to the rear plate 16. The top opening 121 is a rectangular opening and communicates with the rear opening 161. A top half portion and a bottom half portion of the rear plate 16 respectively have a mounting hole group 163. Each of the mounting hole groups 163 includes four screw holes 1631. The four screw holes 1631 are arranged in a rectangular configuration and are respectively configured to fix the fans disposed in the mounting space S through screwing. A plurality of thermal vents 164 is distributed on a whole surface of the rear plate 16 to correspond to the fans. In other embodiments, the rear plate 16 could be provided with one mounting hole group 163 or three or more mounting hole groups 163; a number of the mounting hole group 163 depends on a number of the fans mounted in the mounting space S.

The handle assembly 20 includes a handle body 22, a connecting head 24, and a connecting rod 26. The handle body 22 is a straight rod extending along the top-bottom direction. The connecting head 24 is connected to a top end of the handle body 22. The connecting rod 26 is connected to a bottom end of the handle body 22. The handle body 22 is located directly behind the rear plate 16. The connecting rod 26 is engaged with a portion of the rear plate 16 adjacently connected to the bottom plate 14 by screwing. A connecting surface 241 is formed on a side of the connecting head 24 facing the rear plate 16. A protrusion 242 is formed on a middle of the connecting surface 241. At least one fixing screw hole 243 is formed on the connecting surface 241. In the current embodiment, two fixing screw holes 243 are respectively formed on a left side and a right side of the connecting surface 241 in correspondence to positions of the two fixing through holes 162. Two fixing screws 244 respectively pass through the two fixing through holes 162 and are respectively screwed into the two fixing screw holes 243, so that the connecting surface 241 is engaged with the peripheral edge of the rear opening 161, and the connecting head 24 is engaged with the portion of the rear plate 16 adjacently connected to the top plate 12 by screwing.

The protrusion 242 of the connecting head 24 extends frontwards into the rear opening 161 of the rear plate 16. A through hole 28 penetrates through the protrusion 242 and the connecting head 24 along the front-rear direction L. The through hole 28 is formed inside the protrusion 242 and the connecting head 24. A hook opening 281 is formed on an end of the through hole 28 facing the casing body 10. A trigger opening 282 is formed on another end of the through hole 28 facing away from the casing body 10. In the current embodiment, the handle assembly 20 includes the connecting head 24 and the connecting rod 26. In other embodiments, the handle assembly 20 could be provided without the connecting rod 26, so that the bottom end of the handle body 22 is in a suspended state. Moreover, in the current embodiment, the handle body 22 and the connecting head 24 are engaged with the rear plate 16 of the casing body 10 through screwing. In other embodiments, the handle body 22 and the connecting head 24 could be fixed to the rear plate 16 through riveting or welding.

The linkage switch 30 is mounted in the through hole 28. A hook portion A1 is formed on an end of the linkage switch 30 facing the casing body 10. A trigger portion A2 is formed on another end of the linkage switch 30 facing away from the casing body 10. The hook portion A1 extends out of the hook opening 281. The hook portion A1 passes through the top opening 121, so that the hook portion A1 passes through the top plate 12. The trigger portion A2 is exposed through the trigger opening 282.

In the current embodiment, the linkage switch 30 includes a hook rod 32 and a switch rod 34. The hook rod 32 is located on a front half portion of the through hole 28. A front shaft 321 pivotally passes through a middle of the hook rod 32. Two ends of the front shaft 321 are engaged with a left side and a right side of a hole wall of the through hole 28, so that the hook rod 32 is swingable around the front shaft 321. A spiral spring is connected between the hook rod 32 and the front shaft 321, or a spring is disposed between the hook rod 32 and the hole wall of the through hole 28. In this way, a biasing force for the hook rod 32 to rotate towards the switch rod 34 could be continuously provided by the spiral spring or the spring, so that the hook rod 32 is engaged with the through hole 28 in a manner that the hook rod 32 could return to an original position after swinging. A front end of the hook rod 32 abuts against the hook opening 281. The hook portion A1 is formed on a front end of the connecting rod 26 close to the casing body 10. More specifically, the hook portion A1 is formed on a top side of the front end of the connecting rod 26. An inclined surface A11 is formed on a side of the hook portion A1 facing the casing body 10. An abutted portion 322 is formed on another end of the hook rod 32 facing away from the casing body 10, i.e., a rear end of the hook rod 32.

The switch rod 34 is located on a rear half portion of the through hole 28. A rear shaft 341 pivotally passes through a middle of the switch rod 34. Two ends of the rear shaft 341 are engaged with the left side and the right side of the hole wall of the through hole 28, so that the switch rod 34 is swingable around the rear shaft 341. An abutting portion 342 is formed on an end of the switch rod 34 facing the casing body 10. As the hook rod 32 is subjected to the biasing force provided by the spring to rotate towards the switch rod 34, a bottom side of the abutted portion 322 keeps in continuous contact with a top side of the abutting portion 342. In this way, the abutted portion 322 is continuously in contact with the abutting portion 342, so that when the switch rod 34 swings around the rear shaft 341, the hook rod 32 could be driven to swing in a direction opposite to a swinging direction of the switch rod 34. The trigger portion A2 is formed on another end of the switch rod 34 facing away from the casing body 10. A restoring spring 36 is disposed between an inner side of the trigger portion A2 and the hole wall of the through hole 28.

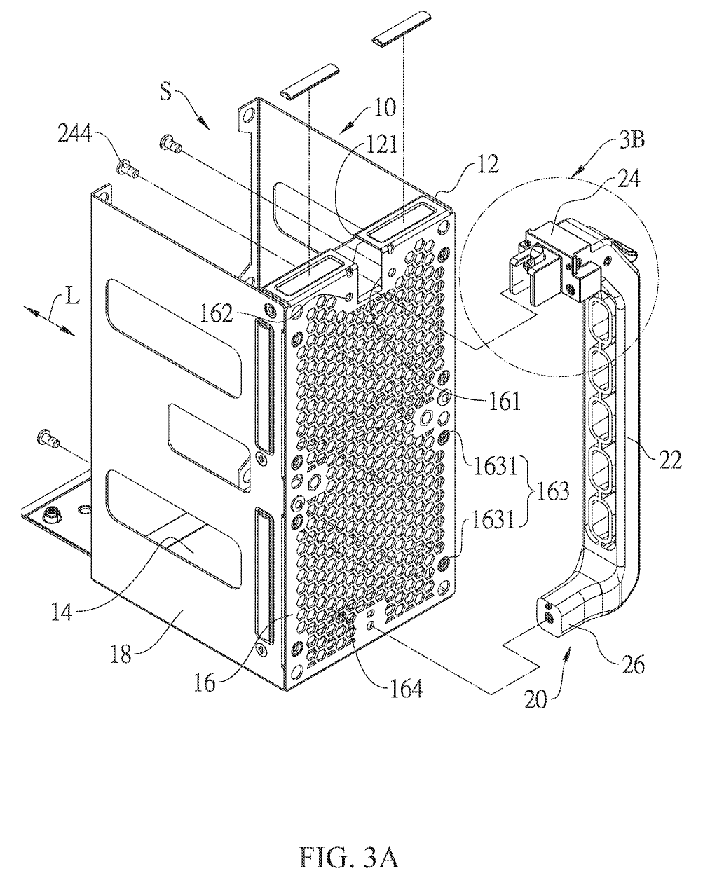

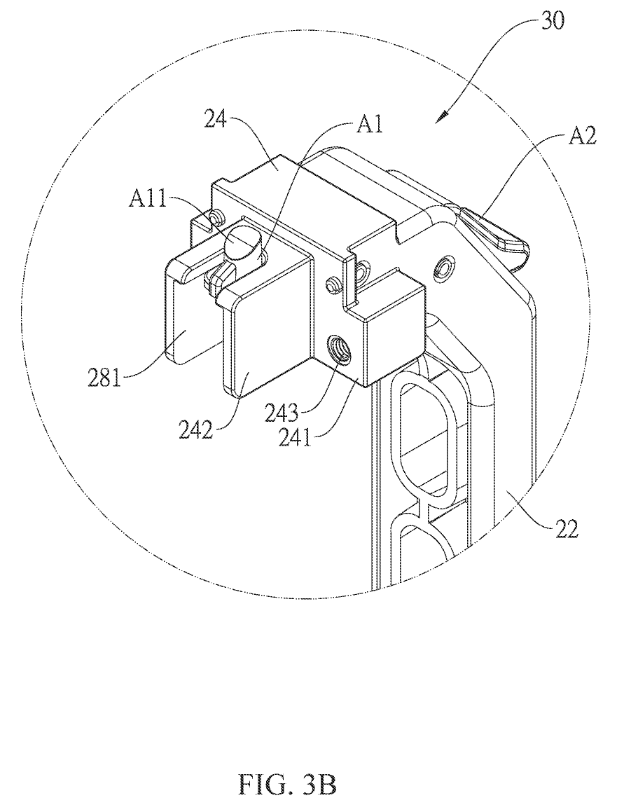

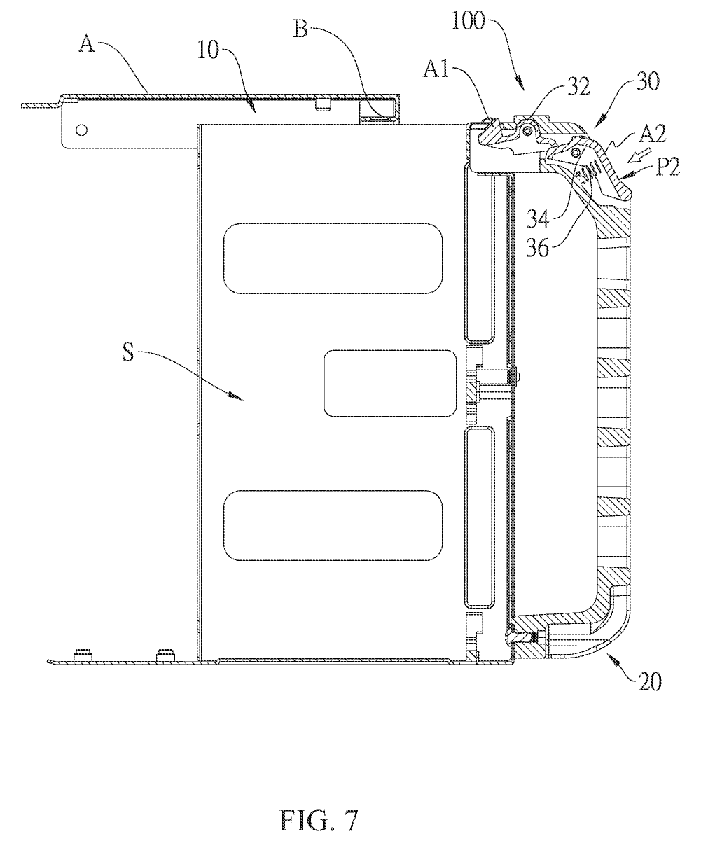

Referring to FIGS. 3A and 5B-7, the switch rod 34 of the linkage switch 30 is operatively coupled to the hook rod 32. When a user presses the trigger portion A2 to move the trigger portion A2 from a first position P1 to a second position P2, the hook portion A1 could be driven to change from a state of extending out of the top opening 121 to retracting into the hook opening 281. When the user releases the trigger portion A2, the restoring spring 36 pushes the trigger portion A2 to return to the first position P1. At the same time, the hook rod 32, which is engaged with the through hole 28 in the manner that the hook rod 32 could restore to the original position after swinging, returns to the original position, so that the hook portion A1 restores to the state of extending out of the top opening 121. While the hook rod 32 and the switch rod 34 are swinging, the abutting portion 342 of the switch rod 34 is continuously in contact with the abutted portion 322 of the hook rod 32.

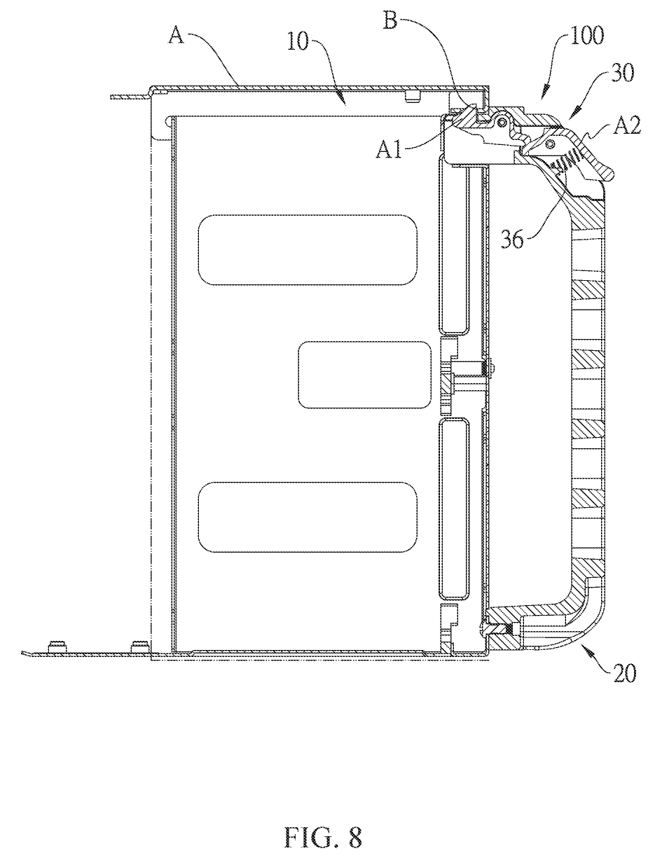

Referring to FIGS. 6-8, when the modular casing 100 with the handle in the present disclosure is used, the two fans are fixed in the mounting space S of the casing body 10, so that the two fans are modularized by being fixed in the casing body 10. Afterwards, the user holds the handle body 22 of the handle assembly 20 and pushes the casing body 10 and the fans inside the casing body 10 frontward into the cabinet A along the front-rear direction L for mounting. After the casing body 10 enters the cabinet A, the hook portion A1 of the linkage switch 30 is engaged with a locking hole B of the cabinet A, so that the casing body 10 and the fans inside the casing body 10 are locked in the cabinet A. When the two fans are required to be removed, the user is simply required to press the trigger portion A2 to drive the hook portion A1 to retract, so that the casing body 10 is released. At that time, the user could remove the casing body 10 from the cabinet A by pulling the handle body 22. In this way, mounting the fans in the cabinet A or repairing and replacing the fans could be time-saving and convenient.

It must be pointed out that the embodiments described above are only some preferred embodiments of the present disclosure. All equivalent structures which employ the concepts disclosed in this specification and the appended claims should fall within the scope of the present disclosure.

What is claimed is:

1. A modular casing with a handle, comprising:
a casing body, having a top plate and a rear plate that are connected to each other, wherein a mounting space is formed inside the casing body, and a rear opening is formed on a portion of the rear plate adjacently connected to the top plate;
a handle assembly, comprising a handle body, wherein an end of the handle body is connected to a connecting head; a connecting surface is formed on a side of the connecting head facing the rear plate; a protrusion is formed on a middle of the connecting surface; the connecting surface is engaged with a peripheral edge of the rear opening; the protrusion extends into the rear opening; a through hole is formed inside the protrusion and the connecting head; a hook opening is formed on an end of the through hole facing the casing body; a trigger opening is formed on another end of the through hole facing away from the casing body; and
a linkage switch, mounted in the through hole, wherein a hook portion is formed on an end of the linkage switch facing the casing body; a trigger portion is formed on another end of the linkage switch facing away from the casing body; the hook portion passes through the top plate of the casing body via the hook opening; the trigger portion is exposed through the trigger opening; the trigger portion is movable between a first position and a second position; when the trigger portion moves from the first position to the second position, the hook portion is driven to change from a state of extending out of the top plate to retracting into the hook opening.

2. The modular casing with the handle as claimed in claim 1, wherein the casing body has a bottom plate; the bottom plate and the top plate face each other; the bottom plate is connected to the rear plate; another end of the handle body is connected to a connecting rod; the connecting rod is engaged with a portion of the rear plate adjacently connected to the bottom plate by screwing.

3. The modular casing with the handle as claimed in claim 2, wherein at least one fixing screw hole is formed on the connecting surface; at least one fixing through hole corresponding to the at least one fixing screw hole is formed on the peripheral edge of the rear opening; at least one fixing screw passes through the at least one fixing through hole and is screwed into the at least one fixing screw hole, so that the connecting head is engaged with the portion of the rear plate adjacently connected to the top plate by screwing.

4. The modular casing with the handle as claimed in claim 1, wherein a top opening is formed on a portion of the top plate adjacently connected to the rear plate; the top opening communicates with the rear opening; the hook portion passes through the top opening.

5. The modular casing with the handle as claimed in claim 4, wherein the casing body has a bottom plate; the bottom plate and the top plate face each other; the bottom plate is connected to the rear plate; the casing body has two lateral plates; the two lateral plates face each other and are connected to the bottom plate; the rear plate is provided with a plurality of thermal vents; the mounting space is formed between the bottom plate, the rear plate, and the two lateral plates.

6. The modular casing with the handle as claimed in claim 5, wherein the rear plate has at least one mounting hole group; the at least one mounting hole group comprises four screw holes; the four screw holes are arranged in a rectangular configuration.

7. The modular casing with the handle as claimed in claim 1, wherein the linkage switch comprises a hook rod and a switch rod; the hook rod is rotatably engaged with a front half portion of the through hole; the hook portion is formed on an end of the hook rod adjacent to the casing body; an abutted portion is formed on another end of the hook rod facing away from the casing body; the switch rod is rotatably engaged with a rear half portion of the through hole; an abutting portion is formed on an end of the switch rod facing the casing body; the trigger portion is formed on another end of the switch rod facing away from the casing body; a restoring spring is disposed between an inner side of the trigger portion and a hole wall of the through hole, so that the abutting portion is continuously in contact with the abutted portion.

8. The modular casing with the handle as claimed in claim 7, wherein a front shaft pivotally passes through a middle of the hook rod; two ends of the front shaft are engaged with the two sides of the hole wall of the through hole located at the front half portion of the through hole of the through hole; a rear shaft pivotally passes through a middle of the switch rod; two ends of the rear shaft are engaged with the another two sides of the hole wall of the through hole located at the rear half portion of the through hole of the through hole.
